(19) United States
(12) Patent Application Publication
(10) Pub. No.: US 2015/0078586 A1
(43) Pub. Date: Mar. 19, 2015

(54) USER INPUT WITH FINGERPRINT SENSOR

(71) Applicant: AMAZON TECHNOLOGIES, INC., Reno, NV (US)

(72) Inventors: POON-KEONG ANG, CUPERTINO, CA (US); DIANA DAN JIANG, IRVINE, CA (US); ROBERT NASRY HASBUN, FALL CITY, WA (US)

(73) Assignee: AMAZON TECHNOLOGIES, INC., Reno, NV (US)

(21) Appl. No.: 14/027,637

(22) Filed: Sep. 16, 2013

(51) Int. Cl. H03G 1/00

(52) U.S. Cl. CPC H03G 1/00
USPC 381/109

(57) ABSTRACT

Devices such as tablets, smartphones, media players, and so forth may incorporate a fingerprint sensor to support acquisition of biometric identification data. As described herein, input data from the fingerprint sensor may be used to control one or more functions of the device. The function controlled may be based at least in part on context of one or more applications executing on the device, direction of motion, and so forth. In one implementation, movement parallel to the fingerprint sensor may modify audio volume settings on the device.

### BACKGROUND

Devices such as tablets, smart phones, media players, eBook reader devices, and so forth allow users to access a wide variety of content. This content may be associated with various endeavors such as ecommerce, communication, medicine, education, and so forth.

### BRIEF DESCRIPTION OF DRAWINGS

FIG. 1 illustrates a device configured to perform one or more commands based at least in part on input data received from a fingerprint sensor.

FIG. 2 illustrates the fingerprint sensor and various axes and motions relative to the sensor.

FIG. 3 illustrates different positions for the fingerprint sensor relative to a case of the device, where the fingerprint sensor is configured to control one or more functions of the device.

FIG. 4 illustrates a cross sectional side view of one implementation of the device in which the fingerprint sensor is arranged under an exterior layer.

FIG. 5 illustrates command association data which determines a particular fingerprint command associated with an application, where the fingerprint command enables control of one or more functions of the device.

FIG. 6 illustrates a block diagram of a device configured to use a fingerprint sensor for controlling one or more functions.

FIG. 7 is a flow diagram of a process of processing input data to determine one or more commands to initiate.

FIG. 8 is a flow diagram of a process of processing input data as commands for a non-identity function or an identity function based at least in part on motion of a finger relative to the fingerprint sensor.

FIG. 9 is a flow diagram of a process of processing input data and determining a command based at least in part on orientation of the fingerprint sensor.

Certain implementations and embodiments will now be described more fully below with reference to the accompanying figures, in which various aspects are shown. However, various aspects may be implemented in many different forms and should not be construed as limited to the implementations set forth herein. Like numbers refer to like elements throughout.

### DETAILED DESCRIPTION

Users may use devices such as tablets, smart phones, media players, eBook reader devices, computer-based tools, laptop computers, and so forth. These devices may be used for entertainment, education, maintenance, medical, and other purposes. These devices may have controls which allow a user to change operation of the device. For example, buttons may be provided which, when activated, allow a user to change volume, scroll through a webpage, and so forth. Inclusion of these controls in the device may increase cost of the device, increase complexity, reduce overall reliability, constrain design, and so forth.

The device may include a fingerprint sensor for use in identifying a particular user. Identification may be used to control access to device functions, authorize payment options, and so forth. For example, a medical device may be configured to use the fingerprint sensor to determine that a previously stored fingerprint is associated with an authorized user such as a nurse before presenting a user interface to make changes in operation of the device. In another example, fingerprint identification may be used to authorize a financial transaction to pay for goods from an ecommerce website.

These fingerprint sensors are configured to generate input data descriptive of one or more physical features of an object proximate to the fingerprint sensor, or within a field of view of one or more detectors. For example, the input data may comprise an image of the user's finger. In some implementations the fingerprint sensor may use a linear arrangement of detectors, also known as a “sweep” sensor. Input data is generated as the object moves past the detectors.

In other implementations, the detector may be configured to acquire information over an area at substantially the same time, also known as an “area sensor”. For example, an imaging chip may capture an image of the user's fingertip at a given instant.

The fingerprint sensors are configured to provide input data which is indicative of the one or more physical features of the object. The input data may indicate the presence or absence of an object, and may also provide information about the relative position of the object with respect to the detectors. For example, the input data may indicate that an object is present and detected at a left end of the sweep sensor, and no object is detected at a right end of the sweep sensor.

Described in this disclosure are techniques and devices for using the input data from one or more fingerprint sensors to initiate commands. These commands may initiate identity-related functions, non-identity related functions, and so forth. The fingerprint sensor may thus be used to accept user input instead of, or in addition to, data associated with fingerprint features as used for identification. In some implementations the fingerprint sensor may be implemented using hardware which provides for a sensor length or area which is larger than those traditionally used only for fingerprint detection. For example, a traditional fingerprint sensor may have a length of about 15 millimeters (“mm”) corresponding to the approximate width of a human fingertip. In some implementations, the fingerprint sensor described in this disclosure may have a length which is between 20 mm and 50 mm.

The additional input functionality provided by using the fingerprint sensor as described herein provides several advantages. For example, the fingerprint sensor may be used to accept user input for control of volume on the device, eliminating the need for separate dedicated volume controls. This reduces the overall cost of materials used in building the device by omitting the need for the dedicated controls. Use of the fingerprint sensor as an input device may also increase overall reliability of the device by eliminating components such as mechanical switches. Additionally, use of the fingerprint sensor as described in this disclosure may remove design constraints imposed by the use of dedicated controls allowing for alternative device designs. For example, removal of the physical switches may facilitate construction which is sealed against environmental factors such as water or dust.

Use of the fingerprint sensor may allow for additional user interface options. In one implementation a rate of motion of the user's finger along the fingerprint sensor may vary the user input. For example, the more quickly the user moves a finger along the sensor, the more rapidly the volume may change. In another implementation, a direction of motion of the user's finger along the fingerprint sensor, such as from a first end to a second end or vice versa may vary the user input. The fingerprint sensor may also be configured to recognize as input touches which are persistent or intermittent. For example, text presented on the display may automatically scroll at a predetermined rate while the finger is on the fingerprint sensor, and stop when the user removes their finger from the fingerprint sensor. In another implementation, a user's intermittent touch or tap to the fingerprint sensor may activate a command such as opening a context menu.

The command activated or deactivated by the presence or absence of input to the fingerprint sensor may vary based on state of the device. The state of the device may include one or more of hardware state or software state. For example, when hardware state of an audio device is muted or disabled, instead of a command to change volume, the input to the fingerprint sensor may be configured to change the brightness of a display device. In another example, when the application is requesting identification functions the fingerprint sensor may be configured to provide identity-related functions, while at other times providing other input and activation of other commands.

In some implementations, directionality of the input with respect to the fingerprint sensor may be determined based at least in part on orientation of the device with respect to the user, three-dimensional space, or both. For example, an accelerometer may be configured to determine a direction of local down relative to the device. Based on this determination, a first end of the fingerprint sensor which is uppermost may be associated with a command to increase a value while a second end of the fingerprint sensor which is lowermost may be associated with a command to decrease a value. Should the device, and the fingerprint sensor, be inverted the associated commands may be swapped. For example, the first end which is now lowermost would be associated with the command to decrease the value while the second end which is now uppermost would be associated with the command to increase the value.

### Illustrative System

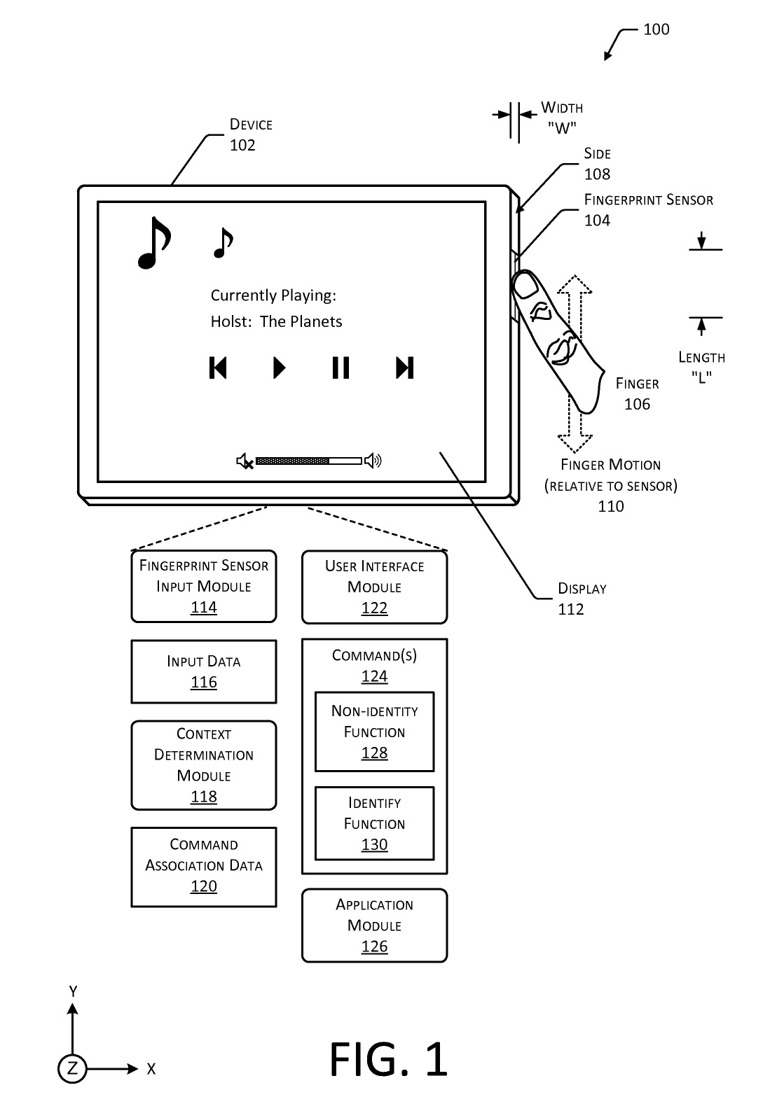

FIG. 1 illustrates an environment 100 which includes a device 102 having one or more fingerprint sensors 104. The device 102 may be a tablet, smart phone, media player, eBook reader device, computer-based tool, laptop computer, input accessory device, and so forth. The device 102 in this illustration is depicted in a “landscape” mode by way of illustration, and not as a limitation.

In one implementation the device 102 may be configured for handheld or portable use. In another implementation, the device 102 may comprise an input accessory device, such as a keyboard or mouse configured for use with a non-portable or semi-portable device, such as a desktop computer or computer-based kiosk.

The fingerprint sensor 104 comprises one or more detectors configured to detect one or more features of a human fingerprint as a human finger 106 moves past a field of view of the one or more detectors. The finger 106 may move past the fingerprint sensor 104 in several ways, including but not limited to knuckle-to-tip, tip-to-knuckle, left side of finger 106 to right side of finger 106, right side of finger 106 to left side of finger 106, and so forth. The fingerprint sensor 104 detectors may include one or more of an optical detector, an electrical capacitance detector, an ultrasonic detector, a thermal detector, a radio frequency receiver, a piezoelectric element, or a microelectromechanical device. The optical detector uses light to gather data. For example, a visible light or infrared illuminator and corresponding visible light or infrared detector may acquire image data of the finger. The electrical capacitance detector measures electrical capacitance of the finger and generates data, such as an image. The ultrasonic detector may use an ultrasonic emitter and receiver to generate data about the finger. The thermal detector may use one or more thermal sensors such as microbolometers to detect heat from the finger and produce corresponding data. The radio frequency receiver receives signals from a radio frequency transmitter to generate data about the finger. The pressure of features of the finger as applied to the piezoelectric element may general electrical signals which may be used to generate data. A microelectromechanical device may mechanically detect the features of the finger, such as by the deflection of one or more microcantilevers. In the implementation depicted here, the fingerprint sensor 104 may be arranged along a side 108 of a case of the device 102.

The detectors in the fingerprint sensor 104 may be configured to produce data from a one dimensional linear array (“sweep”) or a two-dimensional array (“area”). The “sweep” type of fingerprint sensor acquires information about the finger 106 as the finger 106 moves relative to the one-dimensional linear array or row of detectors. In comparison, the “area” type of fingerprint sensor acquires information about the finger 106 at substantially the same time, such as in acquiring an image of the finger 106 using a two-dimensional imaging chip or a two-dimensional microelectromechanical pressure array. Conventional “sweep” fingerprint sensors typically detect input along a length which is less than 15 mm, while conventional “area” fingerprint sensors detect input in a rectangular area less than 15 mm on a side.

The fingerprint sensor 104 illustrated here comprises a “sweep” type sensor which has a sensor length “L” which is greater than 15 mm. The sensor length is the length along a line at which input is accepted. In comparison, an overall length of the fingerprint sensor 104 may be larger. The sensor length “L” of the fingerprint sensor 104 may be at least 19 mm and may be less than 51 mm. Width “W” of the sensor array in the sweep sensor may be less than the length “L”. For example, the width may be less than 5 millimeters. In implementations where an “area” type sensor is used, the length, width, or both may exceed 15 mm.

The extended size of the fingerprint sensor 104 may also facilitate biometric authentication using the device 102. For example, give the wider sensor length, authentication may use two fingers simultaneously rather than a single finger. In another implementation contemporaneous dual-user authentication may be provided. For example, users Alice and Barbara may scan their fingers 106 at the same time on the same fingerprint sensor 104 to authorize a funds transfer from the account of Alice to Barbara.

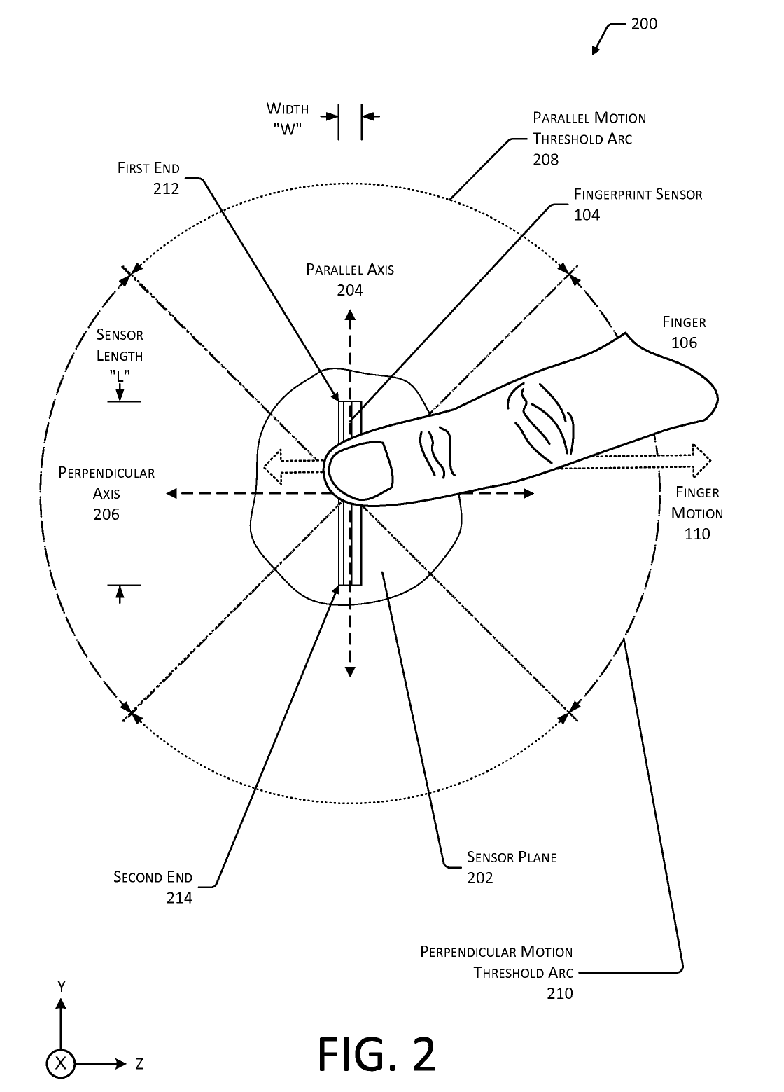

In addition to presence of the finger 106 and information about the features on the finger 106, the fingerprint sensor 104 may be configured to acquire information about one or more of finger position or finger motion 110 between the finger 106 and the fingerprint sensor 104. The relative direction of finger motion 110 may be used to provide input information. For example, an input in which the finger 106 is moved substantially perpendicular to the long or parallel axis of the fingerprint sensor 104 may initiate a command associated with identification. In comparison, finger motion 110 substantially parallel to the long axis of the fingerprint sensor 104 may initiate a non-identify command such as changing a setting for volume, screen brightness, scrolling a window, and so forth. These motions are discussed below in more detail with regard to FIG. 2. A determined location of a touch along the fingerprint sensor 104 may also be used to provide input information. For example, the finger 106 touching a first half of the fingerprint sensor 104 may initiate a first command while the finger 106 touching a second half may initiate a second command.

The finger motion 110 may be independent of the orientation of the finger 106. For example, the finger motion 110 may be along the perpendicular axis 206 such that the finger 106 moves past the fingerprint sensor 104 from joint to tip of the finger 106. In another example, the finger motion 110 may also be along the perpendicular axis 206 when that the finger 106 moves past the fingerprint sensor 104 from a left side of the finger 106 to a right side of the finger 106, such as in a rolling motion.

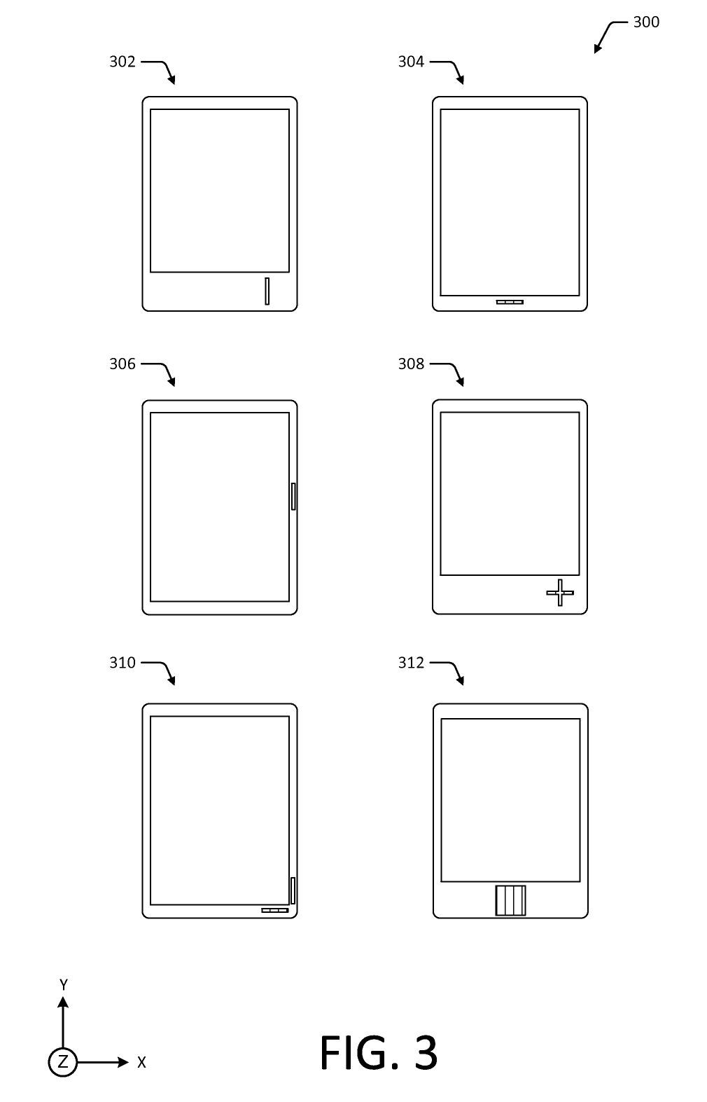

The fingerprint sensor 104 illustrated here is arranged along the side 108 of a case of the device 102, such as to the right of a display 112. While a single fingerprint sensor 104 is depicted, it is understood that in other implementations the device 102 may include additional fingerprint sensors 104 at other locations of the device. Alternative embodiments are discussed below with regard to FIG. 3. The display 112 may comprise one or more of a liquid crystal display, interferometric display, electrophoretic display, light emitting diode display, and so forth.

The fingerprint sensor 104 is configured to couple to a fingerprint sensor input module 114. In some implementations, the fingerprint sensor input module 114 may comprise an application specific integrated circuit or other hardware configured to acquire information from the one or more detectors and generate input data 116. The input data 116 may comprise image data, point data, fingerprint minutia, and so forth. For example, the input data 116 may comprise a series of image frames acquired at twelve frames per second and expressed with 8-bit per pixel grayscale. In some implementations the input data 116 may include vector data, such as apparent direction of motion and magnitude of velocity of a point on the finger 106. This vector data may express the finger motion 110.

A context determination module 118 may be configured to determine current context of the device 102 based at least in part on hardware state, software state, or both. The state information may include, but is not limited to, status of input and output devices, current application focus, predetermined configuration settings, application execution state, and so forth. For example, the context determination module 118 may be configured to determine that an application is waiting to verify the identity of a user.

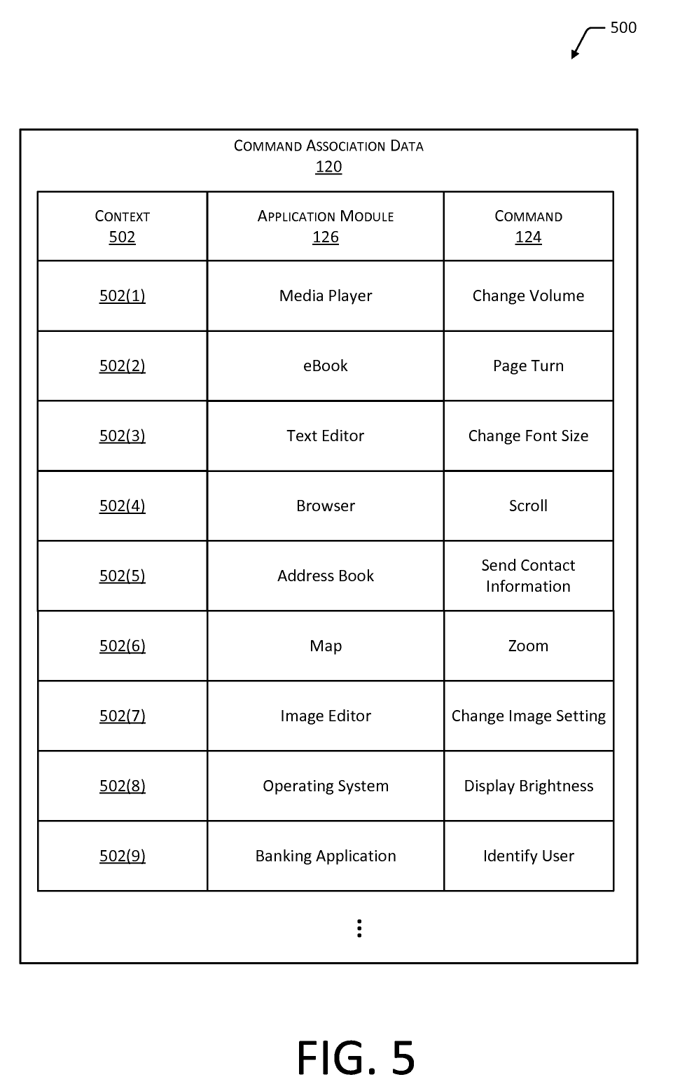

Command association data 120 relates a particular application or hardware setting to a particular command. In one implementation the command association data 120 may comprise a lookup table. For example, a media player application may be associated with commands to increase or decrease volume. The command association data 120 is discussed in more detail below with regard to FIG. 5.

A user interface module 122 is configured to maintain a user interface, providing output to, and receiving input from, the user. The user interface module 122 may use the context as determined by the context determination module 118 and the command association data 120 to determine what commands 124 to provide to one or more application modules 126. The commands 124 may be for non-identity functions 128 or identify functions 130. Non-identity functions 128 are those which relate to control of the device 102, excluding those which generate information identifying the user based on a fingerprint acquired by the fingerprint sensor 104. In comparison, the identity functions 130 are configured to generate information which may be used to identify the user based on the fingerprint acquired by the fingerprint sensor 104. The identity function 130 may include passing the input data 116, or information based thereon, to an external resource such as a server to lookup the identity associated with the fingerprint expressed in the input data 116. In one implementation the identity function 130 may include local identification whereby the input data 116 is compared with internally stored data to determine identity of the finger 106. In another implementation, the identity function 130 may comprise presenting a user interface for a user to input a passcode, select one or more symbols, and so forth.

The user interface module 122 uses the input data 116 and may also use the context information from the context determination module 120 to determine which command 124 to associate, and what application module 126 to provide the command 124 to. The application module 126 may comprise a media player, eBook reader application, browser, shopping application, and so forth. For example, the user interface module 122 may receive the information that the context is that the media player is executing and no identification function is pending. As a result, the user interface module 122 processes the input data 116 as one or more non-identity functions 128 and issues commands 124 to adjust the volume of the media player application module 126.

Using the modules and techniques described in this application, the functionality of the fingerprint sensor 104 is extended to allow for input modes beyond that of acquiring data of a user fingerprint for identification purposes. As a result, the part count of the device 102 may be reduced, overall reliability improved, and so forth. For example, switches for volume control may be removed and the fingerprint sensor 104 may be used instead. Also, additional user input mechanisms may be supported. For example, particular commands 124 may be associated with the finger motion 110, such that different motions result in different actions. As a result, the overall user experience may be improved in terms of hardware cost, reliability, user interface, and so forth.

The device 102 has a case with a front, a back, a top, a bottom, and one or more sides. In this illustration, the top of the device is the portion above the display 112, while the bottom of the device is the portion below the display 112. The front of the device 102 is that which includes the display 112 and faces the user during normal use, while the back is the side opposite which faces away from the user during normal use.

FIG. 2 illustrates various aspects 200 of the fingerprint sensor 104, axes, and motions relative to the sensor. A portion of the fingerprint sensor 104 is depicted here. The portion depicted may comprise a window or section of the detectors used to acquire information about the finger 106 or another object proximate thereto. This portion of the fingerprint sensor 104 is depicted as arranged within a sensor plane 202, such as the side 108. The sensor plane 202 may be flat, curvilinear, and so forth. A linear or “sweep” type detector is depicted here. However, in other implementations the fingerprint sensor 104 may comprise an “area” type detector.

For ease of illustration, and not necessarily as a limitation, a parallel axis 204 is depicted which extends along a longest axis of the detector portion of the fingerprint sensor 104. For example, with a “sweep” type detector the parallel axis 204 runs along the linear array of detectors. At a right angle to the parallel axis 204 is a perpendicular axis 206. The parallel axis 204 and the perpendicular axis 206 may be parallel to, or coplanar with, the plane of the sensor plane 202.

As described above, the fingerprint sensor 104 may be configured to detect finger motion 110 relative to the fingerprint sensor 104. The direction of the finger motion 110 may be used to determine which command 124 will be activated. By way of illustration, and not necessarily as a limitation, parallel motion threshold arcs 208 are depicted extending at 45 degree angles to either size of the parallel axis 204, centered on the fingerprint sensor 104. Located at 90 degrees and also centered on the fingerprint sensor 104 are perpendicular motion threshold arcs 210. Finger motion 110 which is within these arcs may be deemed by the user interface module 122 to be parallel or perpendicular motion, respectively.

The parallel motion threshold arc 208 and the perpendicular motion threshold arc 210 may have different angular sizes. For example, the perpendicular motion threshold arc 210 may extend from 20 degrees to either side of the perpendicular axis 206. Furthermore, a gap or buffer zone may extend between the parallel motion threshold arc 208 and the perpendicular motion threshold arc 210. This gap or buffer zone may be configured such that finger motion 110 within is disregarded.

The angular size of the threshold arcs, presence or size of a buffer zone, and so forth, may vary based on context as determined by the context determination module 118. For example, when the application module 126 for a banking application has focus, the perpendicular motion threshold arc 210 may be set to extend 60 degrees to either size of the perpendicular axis 206 to facilitate the identity function 130.

Portions of the fingerprint sensor 104 may be designated a first end 212 and a second end 214 for ease of discussion in this disclosure. The command association data 120 may be configured to associate a particular end of the fingerprint sensor 104 with a particular command. For example, the first end 212 may be associated with an increase to a value of a setting while the second end 214 may be associated with a decrease to the value of the setting. Continuing this example, a touch of the finger 106 at the first end 212 may initiate a non-identity function 128(1) to increase volume while a touch at the second end 214 may initiate a non-identity function 128(2) to decrease volume.

While the functions described with regard to the fingerprint sensor 104 have been paired, in some implementations different portions of the finger sensor 104 may be associated with non-paired functions. For example, a touch on the first end 212 may open a context sensitive menu for the application currently in focus, while a touch on the second end 214 may mute volume. In some implementations, additional portions of the fingerprint sensor 104 may be associated with different commands 124. For example, a middle section of the fingerprint sensor 104 may be associated with a third command 124 such as locking the device 102.

The direction of finger motion 110 may also be used to designate different commands 124. For example, a finger motion 110(1) in one direction may be associated with a command 124(1) to open a window while a finger motion 110(2) in the opposite direction but within the same paired motion threshold arc may be associated with a command 124(2) to close the window.

The fingerprint sensor 104 may also receive combination motions or gestures. For example, the user may combine motions to generate an “L” shaped gesture in which the finger motion 110(1) begins along the parallel axis 204 and transitions to move along the perpendicular axis 206. The user interface module 122 may be configured to process these gestures as different commands 124. For example, the “L” shaped gesture may be configured to close the application currently in focus.

The finger motion 110 may be determined by comparing position changes of a portion of the finger 106 over time. For example, at a first time, a first position of the finger 106 between a first end and a second end of the fingerprint sensor 104 along the parallel axis 204 is determined. This determination may be made using the input data 116. At a second time, a second position of the finger 106 between the first end and the second end of the fingerprint sensor 104 is determined. A direction of finger motion 110 from the first position to the second position, relative to the fingerprint sensor 104, may thus be determined. In a similar fashion, the finger motion 110 along the perpendicular axis 206 may also be determined. In one implementation fingerprint minutiae or other features of the finger 106 may be tracked to determine the position changes. For example, an arbitrarily selected pattern of fingerprint ridges on the finger 106 may be tracked to determine the finger motion 110.

In the implementation depicted in FIG. 1, the fingerprint sensor 104 comprises a linear arrangement of detectors arranged along the edge 108 or side of the case. A first end of the fingerprint sensor 104 is proximate to the top of the device 102 while a second end of the fingerprint sensor 104 is proximate to the bottom of the device 102. In this configuration, while holding a handheld device 102, the user may easily slide their finger 106 along the parallel axis 204 of the fingerprint sensor 104 to perform various functions, such as increasing or decreasing the volume of the audio device.

FIG. 3 illustrates different positions 300 for the fingerprint sensor 104 relative to a case of the device 102. The fingerprint sensor 104 may be arranged in a variety of different locations with respect to the case. As described above, the fingerprint sensor 104 may be arranged along one of the sides 108 of the device 102, or on a back or rear surface of the device 102.

The devices 102 in this illustration are depicted in a “portrait” mode by way of illustration, and not as a limitation. In other implementations the devices 102 may be oriented in a “landscape” mode. Furthermore, the fingerprint sensors 104 may be arranged on a left or right side of the device 102.

At 302, the fingerprint sensor 104 is depicted as a “sweep” type sensor with the parallel axis 204 extending along a long or “Y” axis of the device 102. In this implementation the fingerprint sensor 104 is arranged below a right-hand side of the display 112. In this position, the fingerprint sensor 104 may be readily accessible to the user's right thumb while grasping the device 102.

At 304, the fingerprint sensor 104 is depicted as a “sweep” type sensor with the parallel axis 204 extending along a second longest or “X” axis of the device 102. In this implementation the fingerprint sensor 104 is centered below the display 112. In this position, the fingerprint sensor 104 may be readily accessible to several of the user's fingers 106 during use.

At 306 the fingerprint sensor 104 is a “sweep” type sensor arranged with the parallel axis 204 extending along a longest or “Y” axis of the device 102. In this implementation the fingerprint sensor 104 is arranged along a right-hand side of the display 112, such as within a bezel of the display 112.

At 308 the fingerprint sensor 104 is a combination “sweep” type sensor having two linear arrays arranged at an angle to one another. In the implementation depicted, the two linear arrays are arranged at right angles to one another. In this implementation the parallel axis 204 for a first fingerprint sensor 104(1) extends along the “Y” axis of the device 102 while the second fingerprint sensor 104(2) extends along the “X” axis. In this implementation the fingerprint sensor 104 is arranged below the display 112 along a right-hand side of the device 102.

At 310 a pair of fingerprint sensors 104(1) and 104(2) of the “sweep” type sensor are shown, arranged at right angles to one another, adjacent to, but not overlapping one another. In this implementation a first fingerprint sensor 104(1) is arranged at a lower right corner of the display 112 with a parallel axis 204 extending along the “Y” axis of the device 102. The second fingerprint sensor 104(2) is arranged under the lower right corner of the display 112 with a parallel axis 204 extending along the “X” axis of the device 102.

At 312, an “area” type fingerprint sensor 104 is depicted centered below the display 112. With this configuration, the user may readily use either thumb for input while grasping the device 102.

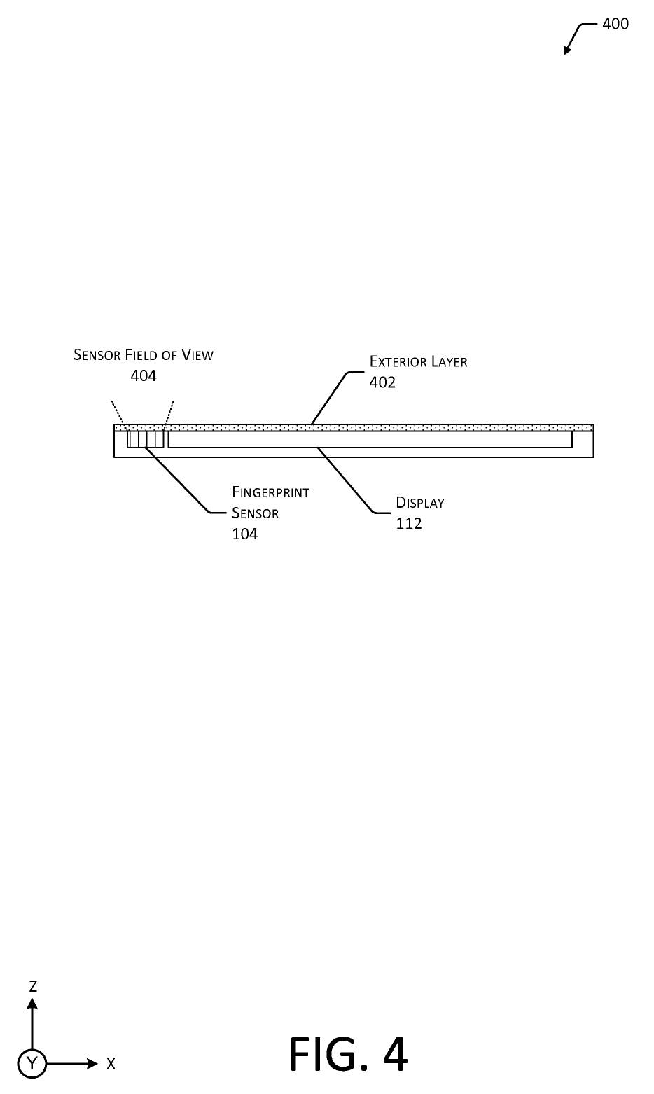

FIG. 4 illustrates a side view 400 of one implementation of the device 102 in which the fingerprint sensor 104 is arranged under an exterior layer. In some implementations the fingerprint sensor 104 may use detectors which are operable through another material such as plastic, glass, ceramics, and so forth. For example, the fingerprint sensor 104 may comprise an infrared sensor configured to detect the heat from the user's finger 106.

In this illustration, an exterior layer 402 is depicted. The exterior layer 402 may comprise a glass, plastic, or other material. In some implementations this material may be optically transparent to visible light. Arranged beneath or behind the exterior layer 402 may be the display 112. The fingerprint sensor 104 is also arranged beneath or behind the exterior layer 402. The fingerprint sensor 104 is configured with a sensor field of view 404 which extends through the exterior layer 402 such that a finger 106 or other object which is proximate to the fingerprint sensor 104 but above or on the surface of the exterior layer 402 is detectable. The other objects may include, but are not limited to a glove, stylus, edge of the user's hand, and so forth.

In these implementations, the device 102 may be more easily produced, sealed against outside contaminants, and so forth because no penetrations to the exterior for the fingerprint sensor 104 is needed. The exterior layer 402 may comprise a material which is not optically transparent to visible light, but through which the fingerprint sensor 104 is operable. For example, where the fingerprint sensor 104 uses a capacitive detector, the exterior layer 402 may comprise an optically opaque plastic or ceramic layer.

As described above, the fingerprint sensor 104 may be configured at different positions relative to the case of the device 102. For example, the fingerprint sensor 104 may be arranged on the side 108 as depicted in FIG. 1, but behind the exterior layer 402.

FIG. 5 illustrates a table 500 in which command association data 120 is stored. The command association data 120 associates a context 502 with the associated application module 126 and one or more command(s) 124.

While a table is depicted, in other implementations one or more other data structures may be used. For example, the command association data 120 may be stored as a linked list, tree, program code, configuration file, and so forth. For example, at least a portion of the command association data 120 may be incorporated within particular applications.

As described above, the user interface module 122 may use the input data 116 and the command association data 120 to determine which, if any, command 124 is associated with the input data 116. The user interface module 122 may initiate the associated command 124 to control one or more functions of the device 102.

The context determination module 118 provides information about the context of the device 102 at a given instant in time. For example, the context may comprise information indicative of which application is in focus and active on the device 102 at that time. Based on the application in focus, the command association data 120 provides the related one or more commands 124. These commands may be non-identity functions 128 or identity functions 130, as described above.

For example, as depicted here the command association data 120 for context 502(1) relates the application module 126 of the media player with the command 124 to change volume on the audio device of the device 102. This command 124 is a non-identity function 128.

The context 502(2) relates the application module 126 of an eBook reader with the command 124 to turn the page in the eBook. This command 124 is a non-identity function 128.

The context 502(3) relates the application module 126 of a text editor or word processor with the command 124 to change the font size in the document. This command 124 is a non-identity function 128.

The context 502(4) relates the application module 126 of a browser with the command 124 to scroll up or down through a presented webpage presented. This command 124 is a non-identity function 128.

The context 502(5) relates the application module 126 of an address book with the command 124 to send contact information to another device 102. For example, a finger motion 110 within the parallel motion threshold arc 208 may result in sending default contact information associated with the user of the device 102 to another device 102. This command 124 is a non-identity function 128.

In some situations, several commands 124 may be associated with the same input data 116. These commands 124 may include one or more non-identity functions 128 and one or more identity functions 130. For example, in another implementation a finger motion 110 which is within the perpendicular motion threshold arc 210 may result in identification of the particular user and the selection and transmission of the contact information for that particular user.

The context 502(6) relates the application module 126 of a map with the command 124 to change zoom or position of the portion of map presented on the display 112. This command 124 is a non-identity function 128.

The context 502(7) relates the application module 126 of an image editor with the command 124 to change one or more image settings of an image presented by the display 112. For example, the image settings may include saturation, hue, brightness, contrast, and so forth. This command 124 is a non-identity function 128.

The context 502(8) relates the operating system with the command 124 to change brightness of the display 112, haptic output level, and so forth. This command 124 is a non-identity function 128.

The context 502(9) relates the application module 126 for online banking with the command 124 to identify the user based on a fingerprint acquired by the fingerprint sensor 104. This command 124 is an identity function 130 in that the input data 116 is used to determine the identity associated with the fingerprint of the finger 106.

Other context's 502 may be associated with other applications modules 126 and commands 124. For example, the context 502 for the media player application module 126 executing while the device 102 is in a low power mode may be associated with the command 124 to wake up the device 102 to a normal operating mode. Several commands 124 may be associated with a particular context 502. Continuing the example, following the command 124 to wake up the device 102, an additional command 124 may present a user interface allowing for entry of a passcode to unlock the device.

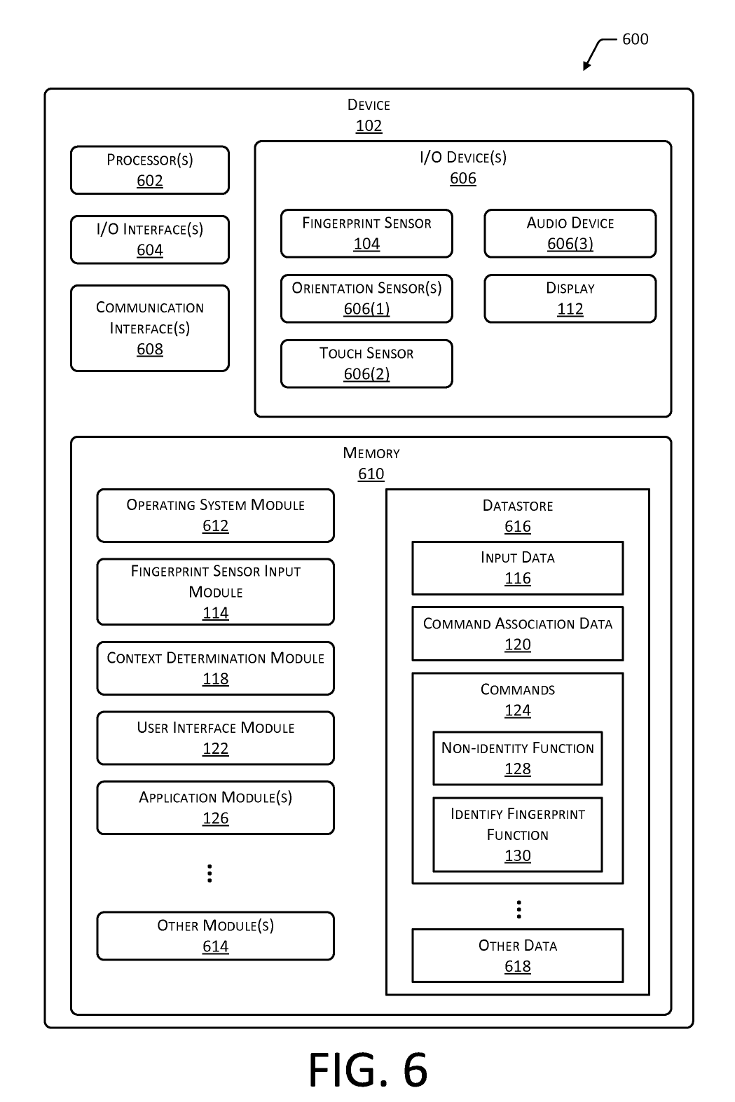

FIG. 6 illustrates a block diagram 600 of the device 102 configured to use a fingerprint sensor 104 for controlling one or more functions. The device 102 may include one or more processors 602 configured to execute one or more stored instructions. The processors 602 may comprise one or more cores. The device 102 may include one or more I/O interface(s) 604 to allow the processor 602 or other portions of the device 102 to communicate with other devices. The I/O interfaces 604 may comprise inter-integrated circuit (“I2C”), serial peripheral interface bus (“SPI”), Universal Serial Bus (“USB”) as promulgated by the USB Implementers Forum, RS-232, and so forth.

The I/O interface(s) 604 may couple to one or more I/O devices 606. The I/O devices 606 may include input devices such as one or more of the fingerprint sensor 104, an orientation sensor 606(1), a touch sensor 606(2), a camera, a microphone, a button, and so forth. The orientation sensor 606(1) may comprise one or more accelerometers, gravimeters, gyroscopes, and so forth. The orientation sensor 606(1) may be configured to determine local down relative to the Earth. The touch sensor 606(2) may be a discrete device, or integrated into the display 112 to provide a touchscreen.

In one implementation the fingerprint sensor 104 may incorporate one or more other sensors, such as a pressure sensor. For example, the fingerprint sensor 104 may include a strain gauge configured to provide an indication of incident force applied to at least a portion of the fingerprint sensor 104. Where the pressure sensor is provided, the input data 116 may include information such as a magnitude of pressure applied to the fingerprint sensor 104 by the finger 106. Selection of the command 124 may be based at least in part on the magnitude of the incident force.

The I/O devices 606 may also include output devices such as one or more of an audio device 606(3), the display 112, haptic output devices, and so forth. The audio device 606(3) may comprise a synthesizer, digital-to-analog converter, and so forth. The audio source may be coupled to one or more speakers to generate audible output. The display 112 may comprise an electrophoretic display, projector, liquid crystal display, interferometric display, light emitting diode display, and so forth. In some embodiments, the I/O devices 606 may be physically incorporated with the device 102 or may be externally placed.

The device 102 may also include one or more communication interfaces 608. The communication interfaces 608 are configured to provide communications between the device 102, routers, access points, servers, and so forth. The communication interfaces 608 may include devices configured to couple to one or more networks including personal area networks, local area networks, wide area networks, wireless wide area networks, and so forth.

The device 102 may also include one or more busses or other internal communications hardware or software that allow for the transfer of data between the various modules and components of the device 102.

As shown in FIG. 6, the device 102 includes one or more memories 610. The memory 610 comprises one or more computer-readable storage media (“CRSM”). The CRSM may be any one or more of an electronic storage medium, a magnetic storage medium, an optical storage medium, a quantum storage medium, a mechanical computer storage medium, and so forth. The memory 610 provides storage of computer readable instructions, data structures, program modules, and other data for the operation of the device 102.

The memory 610 may include at least one operating system (“OS”) module 612. The OS module 612 is configured to manage hardware resource devices such as the I/O interfaces 604, the I/O devices 606, the communication interfaces 608, and provide various services to applications or modules executing on the processors 602. Also stored in the memory 610 may be one or more of the following modules. These modules may be executed as foreground applications, background tasks, daemons, and so forth.

The fingerprint sensor input module 114 is configured to couple to the fingerprint sensor 104 and generate input data 116. In some implementations the fingerprint sensor input module 114 may comprise or work in conjunction with an application specific integrated circuit or other hardware.

As described above, the context determination module 118 may be configured to determine current context of the device 102 based at least in part on hardware state, software state, or both. In some implementations the context determination module 118 may interrogate one or more logs maintained by the OS module 612 to generate the current context.

The user interface module 122 is configured to provide a user interface on the device 102. This user interface may comprise a graphical user interface, audible user interface, haptic user interface, or a combination thereof. The user interface module 122 is configured to process inputs, and provides corresponding outputs to the user, such as on the display 112, using the audio device 606(3), the haptic output device, and so forth. The user interface module 122 is configured to process the input data 116 and generate one or more commands 124. In some implementations the association between application, context, and the commands 124 may be specified in the command association data 120 as described above.

The application modules 126 may comprise a media player, eBook reader application, browser, shopping application, address book application, email application, text messaging application, and so forth. As described above, operation of the application modules 126, the OS module 612, or both may be modified based on the commands 124 resulting from the input data 116 acquired by the fingerprint sensor 104.

Other modules 614 may also be present. For example, application modules to support digital rights manage, speech recognition, and so forth may be present.

The memory 610 may also include a datastore 616 to store information. The datastore 616 may use a flat file, database, linked list, tree, lookup table, executable code, or other data structure to store the information. In some implementations, the datastore 616 or a portion of the datastore 616 may be distributed across one or more other devices including servers, network attached storage devices, and so forth.

As depicted here, the datastore 616 may store the input data 116, the command association data 120, one or more commands 124, and so forth. Other data 618 may also be stored. For example, the other data 618 may include user preferences, configuration files, and so forth.

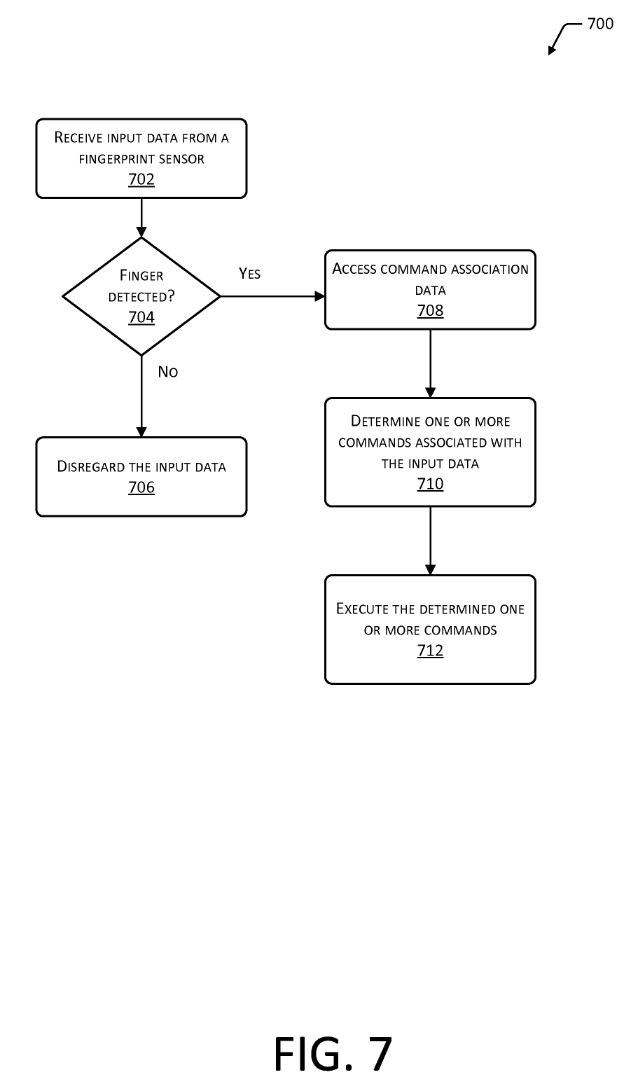

FIG. 7 is a flow diagram 700 of a process of processing the input data 116 to determine and execute one or more commands 124. The user interface module 122 may implement at least a portion of the process 700.

Block 702 receives input data 116 from the fingerprint sensor 104. For example, the fingerprint sensor input module 114 may send the input data 116 to the user interface module 122 using the I2C interface. As described above with regard to FIG. 1, in some implementations the device 102 may have a case with a front and a side 108. The fingerprint sensor 104 may be arranged on the side 108 or edge of the case. The input data 116 may be indicative of one or more physical features of an object proximate to the fingerprint sensor 104. For example, the input data 116 may comprise an optical image, infrared image, capacitive map, and so forth of a portion of the user's finger 106.

In one implementation, the input data 116 may be based on the user moving the finger 106 along the parallel axis 204 of the fingerprint sensor 104. In another implementation, the input data 116 may be based on the user placing one or more fingers 106 at one or more locations on the fingerprint sensor 104. The placement may be sequential, such as at a first location then a second location, or simultaneous. As described above, the fingerprint sensor 104 may comprise a linear array of one or more detectors and the parallel axis 204 extends along a longest axis of the linear array.

Block 704 determines when a finger 106 is detected. This may include analyzing the input data 116 to determine if data indicative of a human finger 106 is present. The determination may include analyzing the input data 116 to look for characteristics which are representative of a finger 106. This determination may be based on the type of fingerprint sensor 104 used, the type of input data 116 acquired, and the characteristics looked for. For example, detection of a periodic pattern in the input data 116 corresponding to a cardiac pulse may result in determination that the finger 106 is present. Information indicative of a presence of hemoglobin may be detected in the input data 116 and used to determine presence of the finger 106. For example, the fingerprint sensor 104 may have light emitters and detectors sensitive to the absorption spectra of human hemoglobin. The input data 116 may be indicative of a temperature, such as where the fingerprint sensor 104 uses one or more microbolometers. The determination a finger 106 is present may be made when the input data 116 indicates a specified temperature range, such as between 36 degrees Celsius to 40 degrees, typical of a living human. Determination of the finger 106 may include detecting in the input data 116 information indicative of presence of one or more dermal features, friction ridges, or other physical structures associated with the finger 106. Several of these techniques to detect the finger 106 may be used in conjunction with one another. For example, the microbolometer fingerprint sensor 104 may use presence of friction ridges and finger temperature to determine the human finger 106 is present.

In some implementations a relative orientation of the user's finger 106 may be determined. For example, based at least in part on an image of at least a portion of the user's fingerprint as acquired by the fingerprint sensor 104, the relative orientation of the finger 106 may be calculated.

When no finger is present, block 704 proceeds to block 706. Block 706 disregards the input data 116. Block 704 may thus be used to reduce or eliminate false or inadvertent activations of the commands 124. In some implementations the determination of block 704 may be omitted, and any object may be used as input. For example, a gloved finger in which the user's finger 106 is obscured may still be used to provide input data 116 using the fingerprint sensor 104.

Returning to block 704, based at least in part on the input data being indicative of a human finger 106, the process proceeds to block 708. Block 708 accesses the command association data 120. As described above, the command association data 120 is indicative of an association between input data 116 and one or more commands 124. In one implementation the one or more commands 124 may be configured to modify audio volume output of the audio device 606(3).

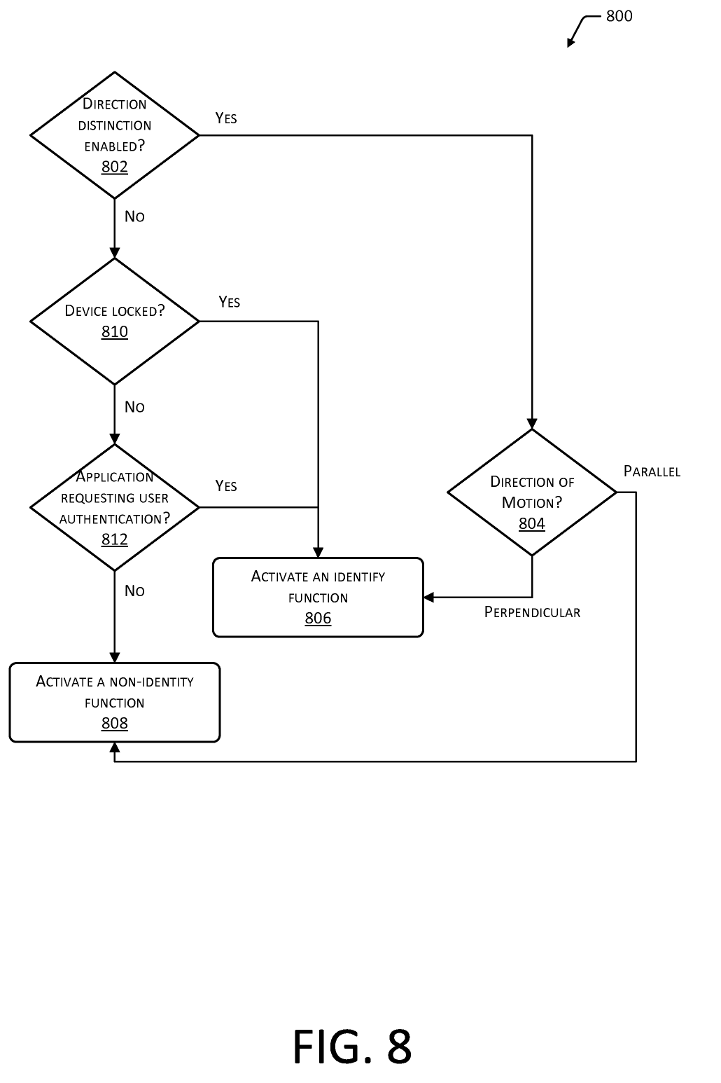

Block 710 determines the one or more commands 124 associated with the input data 116. This determination may be based on the input data 116 and the command association data 120. For example, a particular direction of motion may be associated with particular commands 124, such as described below with regard to FIG. 8. In some implementations the determination may also be based on the context of the device 102 as determined by the context determination module 118, as also described below with regard to FIG. 8. In another example, one or more locations or sections on the fingerprint sensor 104 may be associated with particular commands 124. In such an implementation, the user interface module 122 may be configured to initiate the command 124 after a predetermined interval of the user touching the finger 106 to the fingerprint sensor 104 or removing the finger 106 from the fingerprint sensor 104.

The determination may be made based on one or more of a determined location of the finger 106, gesture, combination of finger motions 110, orientation of the finger 106, and so forth. For example, block 710 may detect the gesture in the input data 116 and determine one or more commands 124 based at least in part on that gesture. A particular set of motions forming the gesture may thus be associated with a particular command 124. In another example, the orientation of the finger 106 relative to the fingerprint sensor 104 may be used to determine the one or more commands 124. Continuing the example, the user's finger 106 being perpendicular to the fingerprint sensor 104 determines the command 124(1) while the user's finger 106 being parallel to the fingerprint sensor 104 determines the command 124(2).

As described above the commands 124 may include non-identity functions 128 or identity functions 130. The non-identity functions 128 are thus not associated with identification of a user associated with a particular finger 106. As also described above, several commands 124 may be associated with the input data 116.

Block 712 executes the determined one or more commands 124. As described in one implementation, the commands 124 may be configured to modify the audio volume output of the audio device 606(3). For example, the volume of the device 102 may be increased or decreased based on the input data 116.

As described above, in some implementations the selection of the one or more commands 124 may be based on direction of the finger motion 110. For example, the modification of the audio volume output may be based at least in part on a direction of motion of the human finger 106 relative to the fingerprint sensor 110.

As also described above, a rate of change of the modification may be proportionate to a speed of the human finger 106 relative to the fingerprint sensor 104. For example, the faster the finger motion 110 the more quickly the audio volume output is changed, such that a fast movement results in a larger change in output volume compared to a slow movement.

In another implementation the selection of the one or more commands 124 may be based on a size of the finger 106. For example, a small finger 106 associated with a child may result in selection of commands 124 which increase or decrease volume, while a large finger 106 associated with an adult may result in selection of commands 124 which scroll content within a window.

FIG. 8 is a flow diagram 800 of a process of processing the input data 116 as commands for a non-identity function 128 or an identity function 130 based at least in part on motion of the finger 106 relative to the fingerprint sensor 104. The user interface module 122 may implement at least a portion of the process 800. The following process may be implicated by block 710 described above. As described above with regard to FIG. 2, in some implementations the direction along which the finger motion 110 is made may be used to select a particular command 124.

Block 802 determines direction distinction is enabled. For example, this determination may comprise accessing a setting within the OS module 612. Following determination that the direction distinction is enabled, the process proceeds to block 804.

Block 804 determines the direction of motion of the finger 106. This may be motion along a first axis or a second axis. In some implementations the first axis and the second axis may be at right angles relative to one another. For example, the input data 116 may be analyzed to determine the finger motion 110 by looking at a relative motion of a point on the finger 106 as described in the input data 116. As described above with regard to FIG. 2, in some implementations the finger motion 110 may be described as along the parallel axis 204 or the perpendicular axis 206.

With a determination that the direction of motion is perpendicular, such as the finger motion 110 being within the perpendicular motion threshold arc 210, the process proceeds to block 806. Block 806 activates an identify function 130. For example, the user interface module 122 may select an identify function 130 configured to process the image of the finger 106 as provided in the input data 116 to determine a match in a datastore of previously stored fingerprints.

Returning to block 804, with a determination that the direction of motion is parallel, such as the finger motion 110 being within the parallel motion threshold arc 208, the process proceeds to block 808. For example, the input data 116 may be indicative of the user moving a finger 106 along the parallel axis 204 of the fingerprint sensor 104, where the fingerprint sensor comprises a linear array of one or more detectors and the parallel axis 204 extends along a longest axis of the linear array. Thus placing or sliding the finger 106 along the fingerprint sensor 104 provides user input.

Block 808 activates a non-identity function 128. For example, the user interface module 122 may select the non-identity function 128 associated with changing the audio output volume of the audio device 606(3).

Returning to block 802, a determination that the direction distinction is disabled may result in the process proceeding to block 810. Block 810 determines the user interface of the device 102 is locked such that user authentication is required to unlock the user interface. For example, while locked the device 102 may present on the display 112 a prompt to enter login credentials. The determination that the device is locked may be made by checking one or more settings within the OS module 612. With block 810 determining the device is locked, the process may proceed to block 806 and activate an identify function 806 to unlock the device.

With a determination by block 810 that the device 102 is unlocked or not locked, the process proceeds to block 812. The user interface may be deemed unlocked when one or more applications are responsive to user input other than entry of a password, fingerprint, and so forth. Block 812 determines whether one or more of the application modules 126 are requesting user authentication or identification information. For example, the application module 126 for a banking application may be requesting user identification to authorize a transfer of funds. Upon a determination by block 812 that one or more of the applications 126 are requesting user authentication or identification information results in the process proceeding to block 806. As described above, block 806 activates the identify functions to process the input data 116 to determine the identity associated with the fingerprint made by the finger 106.

A determination by block 812 that the application is not requesting user authentication results in the process proceeds to block 808. As described above, block 808 activates one or more of the non-identity functions 128. As described above with regard to FIG. 5, the non-identity function 128 may be based on the command association data 120.

The determinations of blocks 802, 810, and 812 may be indicative of the context of the device 102. In some implementations the context determination module 118 may perform these determinations.

In some implementations the selection of the command 124 may be based at least in part on particular direction of the finger motion 110. For example, the finger motion 110 of left-to-right may result in activation of the command 124(1) while the finger motion right-to-left may result in activation of a different command 124(2).

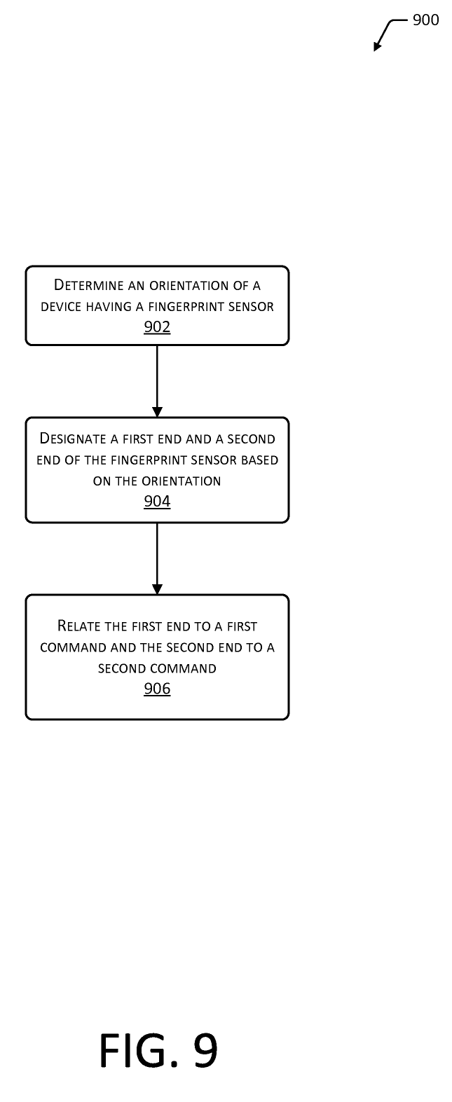

FIG. 9 is a flow diagram 900 of a process of processing the input data 116 and determining a command based at least in part on orientation of the fingerprint sensor 104. The user interface module 122 may implement at least a portion of the process 900.

As described above, in some implementations the one or more commands 124 associated with the input data 116 may be based at least in part on the orientation of the device 102. This may be the orientation of the device 102 relative to the user, to an external reference such as the Earth, or a combination thereof. For example, in one implementation a user-facing camera may be used to acquire one or more images of the face of the user during use of the device 102. Based on the one or more images, it may be determined whether the user is holding the device upside down. In another example, data from the one or more orientation sensors 606(1) may specify the orientation of the device 102 relative to the Earth. In other words, which way is down.

Block 902 determines an orientation of the device 102 in three-dimensional space. For example, the orientation sensors 606(1) may provide information about the directionality of local “down” relative to Earth. In other implementations, the orientation may be relative to the user as described above.

Block 904 designates the first end 212 and the second end 214 of the fingerprint sensor 104 based at least in part on the orientation. In one implementation this determination may be such that the first end 212 is above the second end 214 in three-dimensional space relative to Earth or relative to the orientation of the user's head.

Block 906 configures the system such that the input data 116 indicative of a touch or motion at the first end 212 relates to a first command and the input data 116 indicative of a touch or motion at the second end 214 relates a second command. For example, the first end 212 may be configured such that a touch activates the non-identity function 128 to increase volume while a touch to the second end 214 may be configured to activate the non-identity function 128 to decrease volume. The orientation may thus be used to modify the previously defined association between the input data 116 and the command 124.

Using this process, the commands 124 are thus responsive to the orientation. For example, should the user turn the device 102 upside down, a touch to the highest portion of the fingerprint sensor 104 would increase the volume and a touch to the lowest portion of the fingerprint sensor 104 would decrease the volume.

Those having ordinary skill in the art will readily recognize that certain steps or operations illustrated in the figures above can be eliminated or taken in an alternate order. Moreover, the methods described above may be implemented as one or more software programs for a computer system and are encoded in a computer readable storage medium as instructions executable on one or more processors.

The computer readable storage medium can be any one of an electronic storage medium, a magnetic storage medium, an optical storage medium, a quantum storage medium and so forth. Separate instances of these programs can be executed on or distributed across separate computer systems. Thus, although certain steps have been described as being performed by certain devices, software programs, processes, or entities, this need not be the case and a variety of alternative implementations will be understood by those having ordinary skill in the art.

Additionally, those having ordinary skill in the art readily recognize that the techniques described above can be utilized in a variety of devices, environments and situations.

Although the present disclosure is written with respect to specific embodiments and implementations, various changes and modifications may be suggested to one skilled in the art and it is intended that the present disclosure encompass such changes and modifications that fall within the scope of the appended claims.

What is claimed is:

1. A device comprising:
a fingerprint sensor configured to acquire input data, wherein the input data comprises data indicative of one or more physical features of an object proximate to the fingerprint sensor;
one or more speakers;
an audio device configured to generate audible output using the one or more speakers;
a memory storing computer-executable instructions; and
a processor configured to access the memory and execute the computer-executable instructions to:
receive input data from the fingerprint sensor;
determine the input data is indicative of presence of a finger;
access command association data indicative of an association between input data and one or more commands, wherein the one or more commands are configured to modify audio volume output of the audio device;
determine the one or more commands associated with the input data; and
execute the determined one or more commands to modify volume of the audible output.

2. The device of claim 1, further comprising instructions to:
determine using the input data, at a first time, a first position of the finger between a first end and a second end of the fingerprint sensor;
determine using the input data, at a second time, a second position of the finger between the first end and the second end of the fingerprint sensor;
determine, relative to the fingerprint sensor, a direction of motion of the finger from the first position to the second position;
wherein the determining the one or more commands associated with the input data is based on the direction of the motion such that:
when the direction of motion is towards the first end, the one or more commands are configured to increase the volume of the audible output; and
when the direction of motion is towards the first second, the one or more commands are configured to decrease the volume of the audible output.

3. The device of claim 2, the device further comprising:
a case with a front, a back, a top, a bottom, and a side;
wherein the fingerprint sensor comprises a linear arrangement of detectors having a parallel axis, the fingerprint sensor arranged on the side of the case such that the first end of the parallel axis is proximate to the top and the second end of the parallel axis is proximate to the bottom; and
further wherein the direction of motion of the finger is generally along the parallel axis of the fingerprint sensor.

4. The device of claim 1, wherein the determination the input data is indicative of the finger comprises one or more instructions to:
detect a periodic pattern in the input data corresponding to a cardiac pulse,
detect in the input data information indicative of presence of hemoglobin,
detect a temperature in the input data is within a specified temperature range,
detect in the input data information indicative of presence of one or more dermal features, or
detect in the input data information indicative of presence of one or more friction ridges.

5. A computer-implemented method for controlling a device, the computer-implemented method comprising:
receiving input data from a fingerprint sensor, wherein the fingerprint sensor has a first axis and a second axis arranged at right angles to one another;
accessing command association data indicative of an association between input data and one or more commands;
processing the input data to determine, relative to one or more of the first axis or the second axis of the fingerprint sensor, one or more of motion of a finger, or position of the finger;
determining one or more commands based on one or more of the motion or position of the finger and the command association data; and
executing the one or more determined commands on a processor of the device.

6. The computer-implemented method of claim 5, wherein the fingerprint sensor comprises a linear arrangement of detectors arranged along the first axis, the detectors configured to detect one or more features of a fingerprint within a field of view of the detectors.

7. The computer-implemented method of claim 6, wherein the command association data associates:
the input data indicative of the motion of the finger along the first axis with a command to perform one or more operations other than identification or authentication of the fingerprint, and
the input data indicative of the motion of the finger along the second axis with a command to identify or authenticate a fingerprint.

8. The computer-implemented method of claim 6, further comprising:
determining an orientation of the first axis in three-dimensional space;
designating a first end and a second end of the fingerprint sensor along the first axis based at least in part on the orientation in three-dimensional space; and
wherein the command association data relates input data indicative of one or more of a motion towards the first end or a touch at a position proximate to the first end to a first command and relates input data indicative of one or more of a motion towards the second end or a touch at a position proximate to the second end to a second command.

9. The computer-implemented method of claim 5, wherein the one or more commands are for device functionality other than user identification or authentication.

10. The computer-implemented method of claim 5, the one or more commands comprising instructions to perform, upon execution, one or more of:
changing volume level of an audio output device,
changing pages of an eBook presented on a display device,
changing font size of text presented on the display device,
scrolling contents of a window presented on the display device,
sending contact information to another device,
changing zoom level of information presented on the display device,
changing an image setting of an image presented on the display device, or
changing display brightness of the display device.

11. The computer-implemented method of claim 5, the fingerprint sensor comprising one or more of:
an optical detector,
an electrical capacitance detector,
an ultrasonic detector,
a thermal detector,
a radio frequency receiver,
a piezoelectric element, or
a microelectromechanical device.

12. The computer-implemented method of claim 5, further comprising:
determining the input data comprises information indicative of presence of a finger, the determining comprising one or more of:
detecting a periodic pattern in the input data corresponding to a cardiac pulse,
detecting in the input data information indicative of presence of hemoglobin,
detecting a temperature indicated in the input data is within a specified temperature range,
detecting in the input data information indicative of presence of one or more dermal features, or
detecting in the input data information indicative of presence of one or more friction ridges; and
wherein the determining the one or more commands is based at least in part on the determination that the input data is indicative of presence of a finger.

13. The computer-implemented method of claim 5, further comprising:
detecting in the input data a gesture comprising a combination of motions along the first axis and the second axis; and
wherein the determining the one or more commands is based at least in part on the gesture.

14. The computer-implemented method of claim 5, further comprising:
determining in the input data one or more features on a fingerprint, the features comprising one or more of friction ridges, or dermal features;
comparing the one or more features with a model of a finger to determine the orientation of a finger relative to the fingerprint sensor; and
wherein the determining the one or more commands is further based at least in part on the determined orientation.

15. A computer readable medium storing instructions, which when executed by a processor of a device, cause the processor to perform actions comprising:
accessing input data acquired by a fingerprint sensor;
determining a context of the device, the context based on one or more of state of one or more applications, state of an operating system executing on the processor, or state of hardware of the device;
determining one or more commands based on the input data and the context; and
executing the one or more determined commands on a processor of the device.

16. The computer readable medium of claim 15, wherein a user interface of the device is locked such that user authentication is required to unlock the user interface; and further wherein the one or more determined commands are configured to execute a fingerprint-based authentication function.

17. The computer readable medium of claim 15, wherein a user interface of the device is unlocked such that one or more applications are responsive to user input; and further wherein the one or more determined commands are configured to execute a function other than user identification or authentication.

18. The computer readable medium of claim 17, wherein the one or more determined commands are configured to change a volume level of audio presented by the device.

19. The computer readable medium of claim 15, further comprising:
processing the input data to determine a motion of an finger relative to the fingerprint sensor; and
wherein the determining the one or more commands is further based on the determined motion.

20. The computer readable medium of claim 15, further comprising:
determining the input data is indicative of a presence of a finger, the determining comprising one or more of:
detecting a periodic pattern in the input data corresponding to a cardiac pulse,
detecting in the input data information indicative of presence of hemoglobin,
detecting a temperature in the input data is within a specified temperature range,
detecting in the input data information indicative of presence of one or more dermal features, or
detecting in the input data information indicative of presence of one or more friction ridges; and
wherein the determining one or more commands is further based on the determination that the input data is indicative of a finger.
